(19) United States
(12) Patent Application Publication
(10) Pub. No.: US 2025/0239295 A1
(43) Pub. Date: Jul. 24, 2025

(54) CHIP SELECT SIGNAL CONTROL CIRCUIT, PROCESSING CIRCUIT, AND MEMORY

(71) Applicant: CXMT Corporation, Hefei City (CN)

(72) Inventors: Yanpeng XIE, Hefei City (CN); Zequn HUANG, Hefei City (CN)

(73) Assignee: CXMT Corporation, Hefei City (CN)

(21) Appl. No.: 19/174,819

(22) Filed: Apr. 9, 2025

Related U.S. Application Data
(63) Continuation of application No. PCT/CN2024/095230, filed on May 24, 2024.

(30) Foreign Application Priority Data
Jun. 16, 2023 (CN) 202310725638.0

(51) Int. Cl. G11C 11/4076; G11C 11/408; G11C 11/4093

(52) U.S. Cl. CPC G11C 11/4076; G11C 11/4087; G11C 11/4093

(57) ABSTRACT

Embodiments of the present disclosure disclose a chip select signal control circuit. The chip select signal control circuit includes: a first control signal generation circuit, a second control signal generation circuit, a chip select signal sampling circuit, and a logic control circuit. The first control signal generation circuit outputs a first control signal according to a first chip select sampling signal and a first command address sampling signal obtained in the previous two system sampling periods. The second control signal generation circuit outputs a second control signal according to a second chip select sampling signal and a second command address sampling signal obtained in the previous system sampling period. The logic control circuit controls the output of a current chip select sampling signal according to the first control signal and the second control signal.

### CROSS-REFERENCE TO RELATED APPLICATIONS

The present disclosure is a continuation of International Patent Application No. PCT/CN2024/095230, filed on May 24, 2024, which claims priority to Chinese Patent Application No. 202310725638.0, filed on Jun. 16, 2023. The disclosures of the above-referenced applications are hereby incorporated by reference in their entirety.

### BACKGROUND

In the memory, a command address signal is transmitted through a command address bus, and a chip select signal may be used to indicate whether the command address signal is active. As various command address signals converge on the command address bus, in some specific cases, different decoding errors may be caused.

### SUMMARY

The disclosure relates to the technical field of memories, and in particular to a chip select signal control circuit, a processing circuit, and a memory, which can avoid decoding errors of command address signals.

The embodiments of the present disclosure provide a chip select signal control circuit. The chip select signal control circuit includes:
a first control signal generation circuit, configured to receive a first chip select sampling signal and a first command address sampling signal, and output a first control signal at a first level when levels of the first chip select sampling signal and the first command address sampling signal meet a first preset rule, otherwise, output a first control signal at a second level, where the first chip select sampling signal is obtained by sampling an initial chip select signal in previous two system sampling periods, and the first command address sampling signal is obtained by sampling an initial command address signal in the previous two system sampling periods;
a second control signal generation circuit, configured to receive a second chip select sampling signal and a second command address sampling signal, and output a second control signal at the first level when levels of the second chip select sampling signal and the second command address sampling signal meet a second preset rule, otherwise, output a second control signal at the second level, where the second chip select sampling signal is obtained by sampling the initial chip select signal in a previous system sampling period, and the second command address sampling signal is obtained by sampling the initial command address signal in the previous system sampling period;
a chip select signal sampling circuit, configured to receive the initial chip select signal and a first frequency-divided clock signal, sample the initial chip select signal according to the first frequency-divided clock signal, and output a current chip select sampling signal; and
a logic control circuit, connected to the first control signal generation circuit, the second control signal generation circuit, and the chip select signal sampling circuit, and configured to receive the first control signal, the second control signal, and the current chip select sampling signal and output the current chip select sampling signal when the first control signal and the second control signal meet a third preset rule.

The embodiments of the present disclosure further provide a chip select signal processing circuit. The chip select signal processing circuit includes: the chip select signal control circuit according to the above solution, and a decoding circuit. The decoding circuit is connected to the chip select signal control circuit, and is configured to receive a current chip select sampling signal, decode the current chip select sampling signal, and then output the current chip select sampling signal.

### BRIEF DESCRIPTION OF DRAWINGS

FIG. 1 is a first schematic diagram of signals provided according to an embodiment of the present disclosure;

FIG. 2 is a second schematic diagram of signals provided according to an embodiment of the present disclosure;

FIG. 3 is a first schematic structural diagram of a chip select signal control circuit provided according to an embodiment of the present disclosure;

FIG. 4 is a third schematic diagram of signals provided according to an embodiment of the present disclosure;

FIG. 5 is a fourth schematic diagram of signals provided according to an embodiment of the present disclosure;

FIG. 6 is a second schematic structural diagram of a chip select signal control circuit provided according to an embodiment of the present disclosure;

FIG. 7 is a third schematic structural diagram of a chip select signal control circuit provided according to an embodiment of the present disclosure;

FIG. 8 is a fourth schematic structural diagram of a chip select signal control circuit provided according to an embodiment of the present disclosure;

FIG. 9 is a first schematic structural diagram of a command address sampling circuit provided according to an embodiment of the present disclosure;

FIG. 10 is a fifth schematic structural diagram of a chip select signal control circuit provided according to an embodiment of the present disclosure;

FIG. 11 is a fifth schematic diagram of signals provided according to an embodiment of the present disclosure;

FIG. 12 is a sixth schematic diagram of signals provided according to an embodiment of the present disclosure;

FIG. 13 is a second schematic structural diagram of a command address sampling circuit provided according to an embodiment of the present disclosure;

FIG. 14 is a schematic structural diagram of a chip select signal processing circuit provided according to an embodiment of the present disclosure; and

FIG. 15 is a schematic structural diagram of a memory provided according to an embodiment of the present disclosure.

### DETAILED DESCRIPTION

In order to make the objects, technical solutions, and advantages of the present disclosure clearer, the technical solutions of the present disclosure are further elaborated below with reference to the drawings and embodiments. The described embodiments should not be construed as limiting the present disclosure, and all other embodiments obtained by a person of ordinary skill in the art without making creative efforts fall within the protection scope of the present disclosure.

In the following description, reference is made to “some embodiments” which describe subsets of all possible embodiments, but it can be understood that “some embodiments” may be the same subset or different subsets of all possible embodiments, and may be combined with each other without conflict.

The following description will be added if a similar description of “first/second” appears in the invention document. Reference is made in the following description to the term “first\second\third” merely to distinguish similar objects and not to imply a particular ordering for the objects. It can be understood that “first\second third” may be interchanged with a specific order or sequence if permitted, such that the embodiments of the present disclosure described herein can be implemented in an order other than that shown or described herein.

Unless otherwise defined, all technical and scientific terms used herein have the same meaning as commonly understood by those skilled in the art to which the present disclosure pertains. The terms used herein are for the purpose of describing the embodiments of the present disclosure only and are not intended to limit the present disclosure.

It should be noted that a chip select signal is used to select a corresponding chip. When a plurality of chips are connected to the same bus, the chip select signal is used to distinguish which chip processes data and addresses on the bus, that is, the chip select signal is used to trigger the corresponding chip to enter an operating state. For example, in a memory, a plurality of memory chips are included. To access a memory cell, the CPU (processor) needs to select a memory chip first through a chip select signal, that is, a chip select is performed; then, the corresponding memory cell can be selected from the selected memory chip according to an address code, that is, a word select is performed, so as to read/write data. The chip select signal is generally active low; in the embodiments of the present disclosure, the description is made based on the chip select signal being active low.

In another aspect, a command address signal includes a command signal and an address signal, and is transmitted through a bus. For example, in a dynamic random access memory (DRAM), the command address signal may include: command signals such as a row address strobe (row address strobe, RAS), a column address strobe (column address strobe, CAS), a write command (write, WE), and an activate command (active, ACT) and address signals (for example, addresses A13-A0).

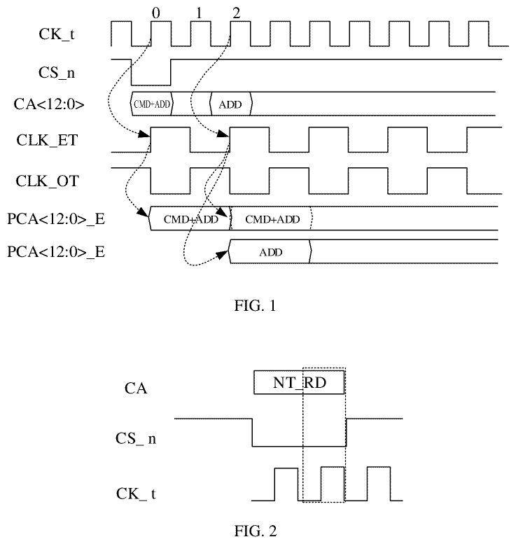

Further, the command address signal needs to be indicated as active by the chip select signal. Referring to FIG. 1, take a 5th double data rate synchronous dynamic random access memory (DDR5 DRAM) design as an example, the command address signal CA<12:0> input may be sampled as an address, or be sampled and decoded as an instruction, that is, the command address signal CA<12:0> includes a command signal CMD and an address signal ADD. After the chip select signal CS_n is indicated as active (that is, the chip select signal CS_n is at a low level), the command address signal CA<12:0> is sampled by an even clock signal CLK_ET for decoding. An odd clock signal CLK_OT and the even clock signal CLK_ET are obtained by frequency division of a clock signal CK_t and are used to sample the command address signal CA<12:0>.

Here, it should be noted that there are two command modes in the DDR5 DRAM, i.e., a 1T CMD and a 2T CMD. The 1T CMD only needs one system sampling period to output the command address signal as the instruction and address; while the command address signal of the 2T CMD needs two system sampling periods to transmit the instruction and address.

It should be further noted that the clock signal CK_t is a basic reference clock in the chip system; and the system sampling periods described in the embodiments of the present disclosure all refer to the period of the clock signal CK_t, which will not be repeated below.

In the signal waveform diagram shown in FIG. 1, the command address signal CA<12:0> is in the 2T CMD mode. Referring to FIG. 1, the command address signal CA<12:0> needs two system sampling periods to transmit the instruction and address. Specifically, the command address signal CA<12:0> transmits the instruction and a portion of the address (i.e., CMD+ADD) in the 0th period of the clock signal CK_t; the command address signal CA<12:0> transmits the other portion of the address (i.e., ADD) in the 2nd period of the clock signal CK_t.

The chip select signal CS_n illustrated in FIG. 1 remains at an active level (i.e., a low level) for only one system sampling period. However, there is a case where the chip select signal CS_n remains at an active level for a plurality of system sampling periods. For example, in a two-rank chip structure, the chip select signal corresponding to an on-die termination command of a non-target chip NT_ODT_CMD remains at an active level for two system sampling periods.

FIG. 2 illustrates the command address signal of the non-target chip and partial waveforms of the chip select signal. As shown in FIG. 2, the command address signal CA includes a read command of the non-target chip NT_RD (i.e., one of the on-die termination commands), and accordingly, the duration in which the chip select signal CS_n remains at an active level is two periods of the clock signal CK_t. As such, in the second system sampling period in which the chip select signal CS_n remains at an active level, the address (the portion outlined by dotted lines) transmitted by the command address signal CA may be mistaken for the instruction, which may result in erroneous sampling and decoding.

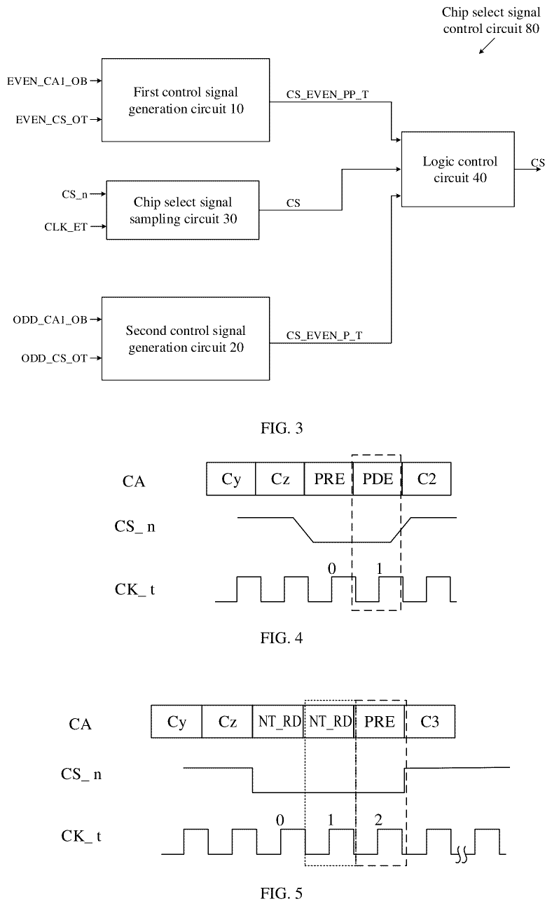

FIG. 3 is an optional schematic structural diagram of a chip select signal control circuit provided according to an embodiment of the present disclosure. As shown in FIG. 3, the chip select signal control circuit 80 includes: a first control signal generation circuit 10, a second control signal generation circuit 20, a chip select signal sampling circuit 30, and a logic control circuit 40.

The first control signal generation circuit 10 is configured to receive a first chip select sampling signal EVEN_CS_OT and a first command address sampling signal EVEN_CA1_OB, and output a first control signal CS_EVEN_PP_T at a first level when levels of the first chip select sampling signal EVEN_CS_OT and the first command address sampling signal EVEN_CA1_OB meet a first preset rule, otherwise, output a first control signal CS_EVEN_PP_T at a second level. The first chip select sampling signal EVEN_CS_OT is obtained by sampling an initial chip select signal CS_n in the previous two system sampling periods, and the first command address sampling signal EVEN_CA1_OB is obtained by sampling an initial command address signal in the previous two system sampling periods.

The second control signal generation circuit 20 is configured to receive a second chip select sampling signal ODD_CS_OT and a second command address sampling signal ODD_CA1_OB, and output a second control signal CS_EVEN_P_T at the first level when levels of the second chip select sampling signal ODD_CS_OT and the second command address sampling signal ODD_CA1_OB meet a second preset rule, otherwise, output a second control signal CS_EVEN_P_T at the second level. The second chip select sampling signal ODD_CS_OT is obtained by sampling the initial chip select signal CS_n in the previous system sampling period, and the second command address sampling signal ODD_CA1_OB is obtained by sampling the initial command address signal in the previous system sampling period.

The chip select signal sampling circuit 30 is configured to receive the initial chip select signal CS_n and a first frequency-divided clock signal CLK_ET (i.e., an even clock signal), sample the initial chip select signal CS_n according to the first frequency-divided clock signal CLK_ET, and output a current chip select sampling signal CS.

The logic control circuit 40 is connected to the first control signal generation circuit 10, the second control signal generation circuit 20, and the chip select signal sampling circuit 30, and is configured to receive the first control signal CS_EVEN_PP_T, the second control signal CS_EVEN_P_T, and the current chip select sampling signal CS and output the current chip select sampling signal CS when the first control signal CS_EVEN_PP_T and the second control signal CS_EVEN_P_T meet a third preset rule.

It should be noted that, in FIG. 3, the first chip select sampling signal EVEN_CS_OT and the first command address sampling signal EVEN_CA1_OB are obtained by sampling using the even clock signal CLK_ET; the second chip select sampling signal ODD_CS_OT and the second command address sampling signal ODD_CA1_OB are obtained by sampling using the odd clock signal CLK_OT (not shown in FIG. 3).

As can be seen from FIG. 1, the odd clock signal CLK_OT and the even clock signal CLK_ET are obtained by frequency division of the clock signal CK_t; that is, the frequency of the odd clock signal CLK_OT or the frequency of the even clock signal CLK_ET is half the frequency of the clock signal CK_t; the period of the odd clock signal CLK_OT and the period of the even clock signal CLK_ET is twice the period of the clock signal CK_t.

Still referring to FIG. 1, the odd clock signal CLK_OT and the even clock signal CLK_ET are inverted relative to each other. Thus, if any sampling edge (rising edge) of the even clock signal CLK_ET is used as the current sampling edge, the sampling edge (rising edge) of the odd clock signal CLK_OT occurs one system sampling period earlier (i.e., half a period of the even clock signal CLK_ET earlier) than the current sampling edge; furthermore, the previous sampling edge (rising edge) of the even clock signal CLK_ET occurs two system sampling periods earlier (i.e., one period of the even clock signal CLK_ET earlier) than the current sampling edge.

With reference to FIGS. 1 and 3, the chip select signal sampling circuit 30 receives the initial chip select signal CS_n and samples the initial chip select signal according to the even clock signal CLK_ET, so as to obtain the current chip select sampling signal CS. Thus, the sampling edge of the even clock signal CLK_ET occurs two system sampling periods earlier than the moment when the current chip select sampling signal CS is sampled, that is, the first chip select sampling signal EVEN_CS_OT is obtained by sampling the initial chip select signal CS_n using the even clock signal CLK_ET in the previous two system sampling periods; accordingly, the first command address sampling signal EVEN_CA1_OB is obtained by sampling the initial command address signal using the even clock signal CLK_ET in the previous two system sampling periods. Similarly, the sampling edge of the odd clock signal CLK_OT occurs one system sampling period earlier than the moment when the current chip select sampling signal CS is sampled, that is, the second chip select sampling signal ODD_CS_OT is obtained by sampling the initial chip select signal CS_n using the odd clock signal CLK_OT in the previous system sampling period; accordingly, the second command address sampling signal ODD_CA1_OB is obtained by sampling the initial command address signal using the odd clock signal CLK_OT in the previous system sampling period.

FIGS. 4 and 5 respectively show waveforms of different command address signals CA when the chip select signal CS_n remains at an active level for a plurality of system sampling periods.

Referring to FIG. 4, the command address signal CA includes two consecutive commands (i.e., PRE and PDE) of the 1T CMD mode, and the chip select signal CS_n remains at an active level for two system sampling periods. As such, sampling according to the chip select signal CS_n may result in the second command PDE being canceled.

Referring to FIG. 3, the second control signal generation circuit 20 in the embodiments of the present disclosure outputs the second control signal CS_EVEN_P_T according to the second chip select sampling signal ODD_CS_OT and the second command address sampling signal ODD_CA1_OB obtained in the previous system sampling period. That is, with reference to FIG. 4, the second control signal generation circuit 20 may make a comprehensive determination according to the levels at which the two signals (the chip select signal CS_n and the command address signal CA) are in the previous system sampling period. For example, in the previous system sampling period, when the chip select signal CS_n is at a low level and the identification signal in the command address signal CA is at a high level, the current command PDE may be determined to be a complete command, and the current command PDE can be normally sampled and decoded when the chip select signal CS_n is at a low level.

Referring to FIG. 5, the read command of the non-target chip NT_RD (i.e., one of the on-die termination commands) lasts for two system sampling periods, followed by one command PRE. As such, sampling according to the chip select signal CS_n may result in the command PRE being erroneously used as the second system sampling period of the 2T CMD mode.

Referring to FIG. 3, the first control signal generation circuit 10 in the embodiments of the present disclosure outputs the first control signal CS_EVEN_PP_T according to the first chip select sampling signal EVEN_CS_OT and the first command address sampling signal EVEN_CA1_OB obtained in the previous two system sampling periods. That is, with reference to FIG. 5, the first control signal generation circuit 10 may make a comprehensive determination according to the levels at which the two signals (the chip select signal CS_n and the command address signal CA) are in the previous two system sampling periods. For example, in the previous two system sampling periods, when the chip select signal CS_n is at a low level and the command address signal CA is represented as the read command of the non-target chip NT_RD, the current command PDE may be determined to be a complete command, and the current command PDE can be normally sampled and decoded when the chip select signal CS_n is at a low level, thereby preventing the read command NT_RD from being erroneously decoded in the second system sampling period.

It can be understood that as various command address signals converge on the command address bus, different decoding errors may be caused. In the embodiments of the present disclosure, the first control signal generation circuit obtains the first control signal according to the levels at which the chip select signal and the command address signal are in the previous two system sampling periods. The second control signal generation circuit obtains the second control signal according to the levels at which the chip select signal and the command address signal are in the previous system sampling period. Furthermore, the logic control circuit controls the output of the current chip select sampling signal (i.e., controls whether the chip select signal acts on the current command address signal) according to the first control signal and the second control signal. As such, the signals in the previous system sampling period and the previous two system sampling periods are used for a logic check, such that the command address signal in the current system sampling period can be ensured to be normally decoded, thereby avoiding decoding errors.

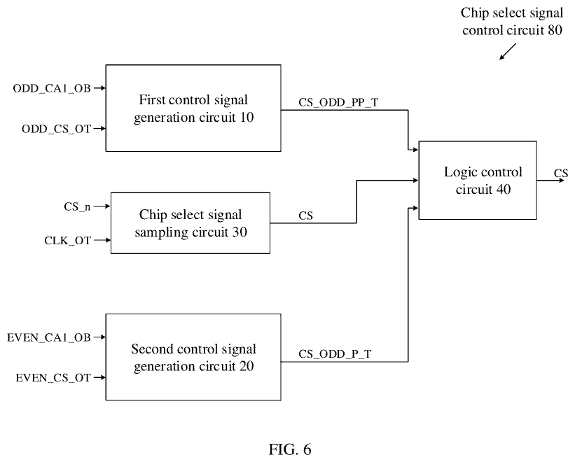

FIG. 6 is another optional schematic structural diagram of a chip select signal control circuit provided according to an embodiment of the present disclosure. FIG. 6 illustrates that the chip select signal sampling circuit 30 receives the initial chip select signal CS_n and samples the initial chip select signal according to the odd clock signal CLK_OT, so as to obtain the current chip select sampling signal CS. That is, FIG. 6 illustrates a circuit structure corresponding to FIG. 3, and signals illustrated in FIG. 6 can be derived by referring to FIG. 3.

Specifically, referring to FIG. 6, the first control signal generation circuit 10 is configured to receive a first chip select sampling signal ODD_CS_OT and a first command address sampling signal ODD_CA1_OB, and output a first control signal CS_ODD_PP_T at a first level when levels of the first chip select sampling signal ODD_CS_OT and the first command address sampling signal ODD_CA1_OB meet the first preset rule, otherwise, output a first control signal CS_ODD_PP_T at a second level. The first chip select sampling signal ODD_CS_OT is obtained by sampling the initial chip select signal CS_n in the previous two system sampling periods, and the first command address sampling signal ODD_CA1_OB is obtained by sampling the initial command address signal in the previous two system sampling periods.

The second control signal generation circuit 20 is configured to receive a second chip select sampling signal EVEN_CS_OT and a second command address sampling signal EVEN_CA1_OB, and output a second control signal CS_ODD_P_T at the first level when levels of the second chip select sampling signal EVEN_CS_OT and the second command address sampling signal EVEN_CA1_OB meet the second preset rule, otherwise, output a second control signal CS_ODD_P_T at the second level. The second chip select sampling signal EVEN_CS_OT is obtained by sampling the initial chip select signal CS_n in the previous system sampling period, and the second command address sampling signal EVEN_CA1_OB is obtained by sampling the initial command address signal in the previous system sampling period.

The chip select signal sampling circuit 30 is configured to receive the initial chip select signal CS_n and the odd clock signal CLK_OT, sample the initial chip select signal CS_n according to the odd clock signal CLK_OT, and output the current chip select sampling signal CS.

The logic control circuit 40 is connected to the first control signal generation circuit 10, the second control signal generation circuit 20, and the chip select signal sampling circuit 30, and is configured to receive the first control signal CS_ODD_PP_T, the second control signal CS_ODD_P_T, and the current chip select sampling signal CS and output the current chip select sampling signal CS when the first control signal CS_ODD_PP_T and the second control signal CS_ODD_P_T meet the third preset rule.

It can be understood that FIGS. 3 and 6 illustrate circuit structures, each corresponding to a different sampling clock. If the initial chip select signal CS_n is sampled using the even clock signal CLK_ET, the circuit shown in FIG. 3 is operated; if the initial chip select signal CS_n is sampled using the odd clock signal CLK_OT, the circuit shown in FIG. 6 is operated. The specific setting can be made according to the actual situations in the chip system.

Accordingly, in the circuit shown in FIG. 6, the first chip select sampling signal ODD_CS_OT is obtained by sampling the initial chip select signal CS_n using the odd clock signal CLK_OT in the previous two system sampling periods; the first command address sampling signal ODD_CA1_OB is obtained by sampling the initial command address signal using the odd clock signal CLK_OT in the previous two system sampling periods; the second chip select sampling signal EVEN_CS_OT is obtained by sampling the initial chip select signal CS_n using the even clock signal CLK_ET in the previous system sampling period; the second command address sampling signal EVEN_CA1_OB is obtained by sampling the initial command address signal using the even clock signal CLK_ET in the previous system sampling period.

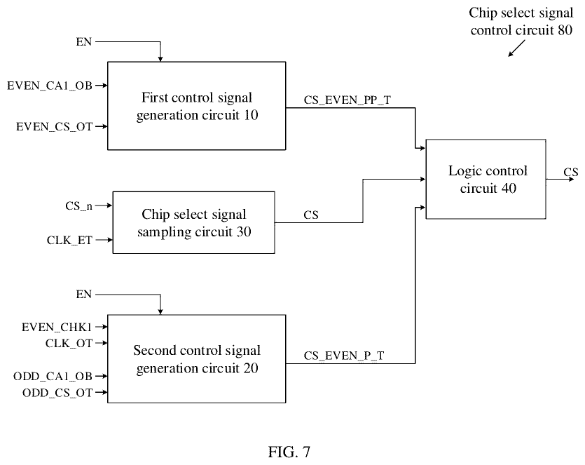

In some embodiments of the present disclosure, referring to FIG. 7, the second control signal generation circuit 20 is further configured to receive the first control signal EVEN_CHK1 after a first delay and a second frequency-divided clock signal CLK_OT (i.e., the odd clock signal), sample the first control signal EVEN_CHK1 after the first delay according to the second frequency-divided clock signal CLK_OT, and output the second control signal CS_EVEN_P_T.

Still referring to FIG. 7, the first control signal generation circuit 10 is further configured to, in a first operating mode, apply a second delay to the first control signal and then output the first control signal; or, in a second operating mode, output the first control signal.

It should be noted that, in a memory (e.g., a DRAM), there are two operating modes, i.e., a 1N mode and a 2N mode. In the 1N mode, both the odd clock signal CLK_OT and the even clock signal CLK_ET are sampled; in the 2N mode, only one of the odd clock signal CLK_OT and the even clock signal CLK_ET is sampled.

In FIG. 7, the level at which an operating mode enable signal EN is represents the operating mode in which the memory is. For example, when the operating mode enable signal EN is at a high level, the memory is represented as being in the 1N mode (i.e., the first operating mode); when the operating mode enable signal EN is at a low level, the memory is represented as being in the 2N mode (i.e., the second operating mode). That is, the chip select signal control circuit 80 provided according to the embodiments of the present disclosure may also make corresponding adjustments according to different operating modes of the memory.

Referring to FIG. 7, for the first control signal generation circuit 10, in the 1N mode, the first control signal CS_EVEN_PP_T output by the first control signal generation circuit 10 is applied with the second delay; in the 2N mode, the first control signal CS_EVEN_PP_T output by the first control signal generation circuit 10 is not applied with the second delay. Applying the second delay may allow the output first control signal CS_EVEN_PP_T to be timing matched to other signals in the 1N mode.

Still referring to FIG. 7, for the second control signal generation circuit 20, in the 1N mode, the second control signal generation circuit 20 outputs the second control signal CS_EVEN_P_T according to the second chip select sampling signal ODD_CS_OT and the second command address sampling signal ODD_CA1_OB; in the 2N mode, the second control signal generation circuit 20 samples the first control signal EVEN_CHK1 after the first delay and then output the sampled signal.

It should be noted that, in the circuit illustrated in FIG. 7, in the 2N mode, the even clock signal CLK_ET samples the initial chip select signal CS_n, that is, the odd clock signal CLK_OT does not sample in this case. As such, the second chip select sampling signal ODD_CS_OT and the second command address sampling signal ODD_CA1_OB obtained by sampling using the odd clock signal CLK_OT cannot be applied to the 2N mode. Therefore, in the 2N mode, the second control signal generation circuit 20 may sample the first control signal EVEN_CHK1 after the first delay according to the odd clock signal CLK_OT, thereby replacing the logic check of the signal in the previous system sampling period, so as to output the second control signal CS_EVEN_P_T.

Accordingly, in the circuit shown in FIG. 8, in the 2N mode, the initial chip select signal CS_n is sampled by the odd clock signal CLK_OT. Referring to FIG. 8, the second control signal generation circuit 20 is further configured to receive the first control signal ODD_CHK1 after the first delay and a second frequency-divided clock signal CLK_ET (i.e., the even clock signal), sample the first control signal ODD_CHK1 after the first delay according to the second frequency-divided clock signal CLK_ET, and output the second control signal CS_EVEN_P_T.

It can be understood that the chip select signal control circuit provided according to the embodiments of the present disclosure can make corresponding adjustments according to different operating modes of the memory. As such, the chip select signal control circuit can better adapt to different operating modes of the memory, thereby expanding the application range of the circuit.

In some embodiments of the present disclosure, the chip select signal control circuit further includes: a command address signal sampling circuit. The command address signal sampling circuit is configured to receive the initial command address signal, the first frequency-divided clock signal, and the second frequency-divided clock signal, sample the initial command address signal into the first command address sampling signal according to the first frequency-divided clock signal, and sample the initial command address signal into the second command address sampling signal according to the second frequency-divided clock signal.

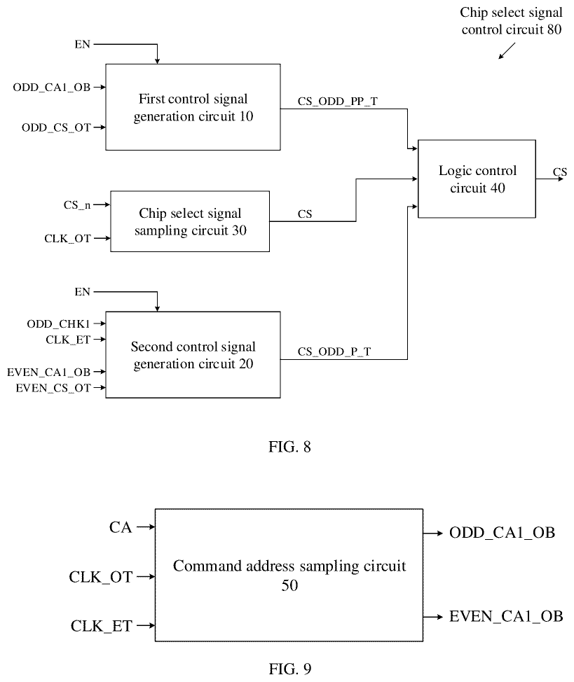

That is, referring to FIG. 9, the command address signal sampling circuit 50 may sample the initial command address signal CA according to the odd clock signal CLK_OT and output a command address sampling signal ODD_CA1_OB. The command address signal sampling circuit 50 may also sample the initial command address signal CA according to the even clock signal CLK_ET and output a command address sampling signal EVEN_CA1_OB. The command address sampling signals ODD_CA1_OB and EVEN_CA1_OB serve as input signals in FIGS. 3, 6, 7, and 8.

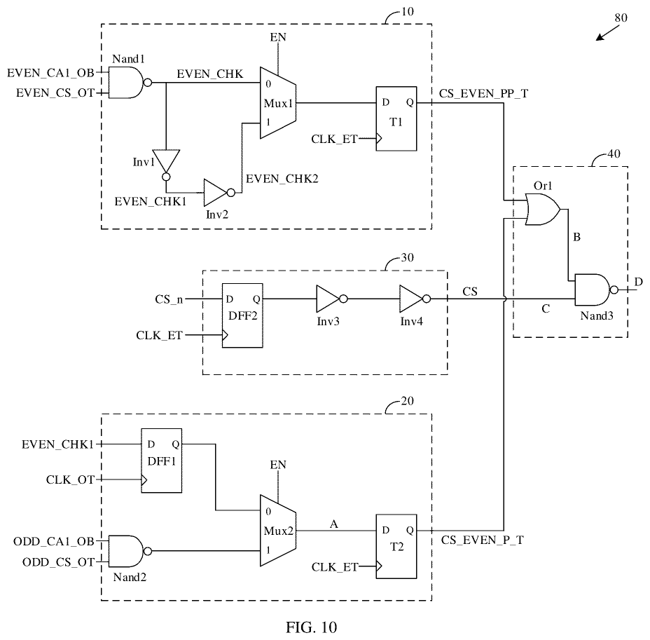

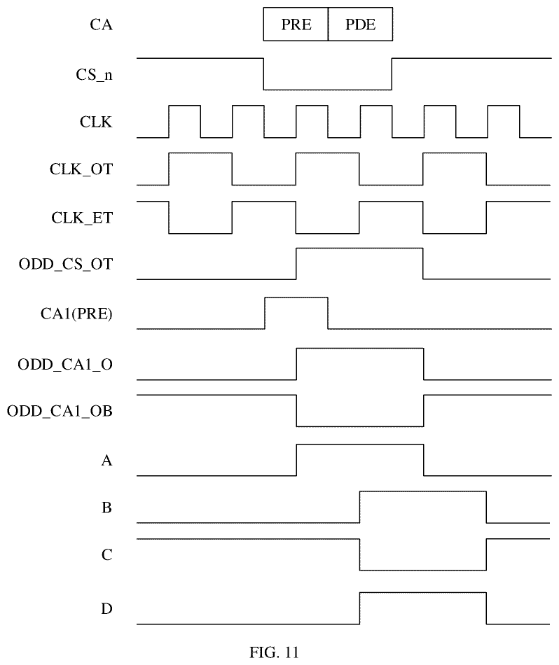

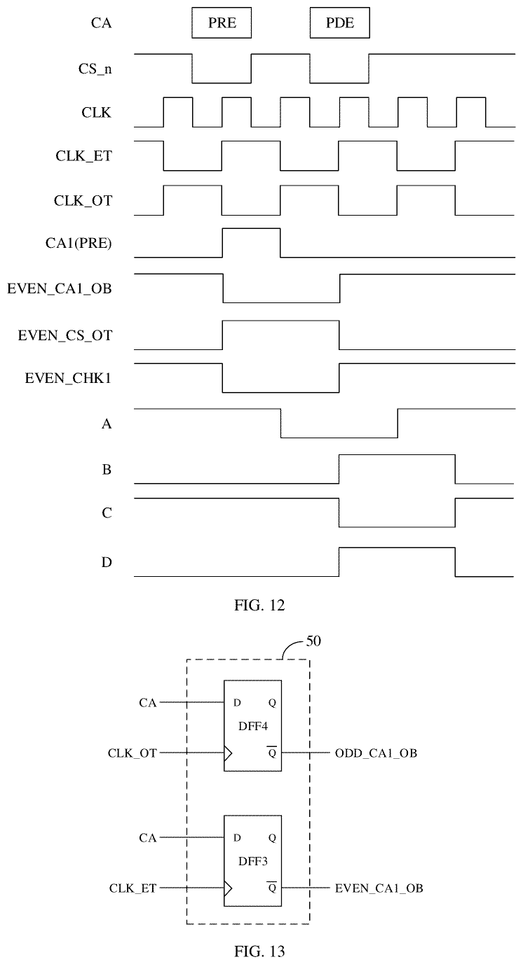

FIG. 10 is an optional schematic structural diagram of a chip select signal control circuit provided according to an embodiment of the present disclosure. FIGS. 11 and 12 are schematic diagrams of waveforms of part of signals in FIG. 10. FIG. 11 illustrates waveforms of part of signals of the memory in the 1N mode; that is, both the odd clock signal CLK_OT and the even clock signal CLK_ET in FIG. 11 are used for sampling. FIG. 12 illustrates waveforms of part of signals of the memory in the 2N mode; in FIG. 12, only the even clock signal CLK_ET is used for sampling.

In some embodiments of the present disclosure, referring to FIG. 10, the first control signal generation circuit 10 includes: a first NAND gate Nand1, a first inverter Inv1, and a second inverter Inv2. Input terminals of the first NAND gate Nand1 respectively receive the first chip select sampling signal EVEN_CS_OT and the first command address sampling signal EVEN_CA1_OB, and the output terminal of the first NAND gate Nand1 is connected to the input terminal of the first inverter Inv1. The output terminal of the first inverter Inv1 is connected to the input terminal of the second inverter Inv2. The first NAND gate Nand1 outputs the first control signal EVEN_CHK, the first inverter Inv1 outputs the first control signal EVEN_CHK1 after the first delay, and the second inverter Inv2 outputs the first control signal EVEN_CHK2 after the second delay.

Still referring to FIG. 10, the first control signal generation circuit 10 further includes: a first data selector Mux1. A first input terminal (i.e., a “1” input terminal) of the first data selector Mux1 receives the first control signal EVEN_CHK2 after the second delay, a second input terminal (i.e., a “0” input terminal) of the first data selector Mux1 receives the first control signal EVEN_CHK, and the control terminal of the first data selector Mux1 receives the operating mode enable signal EN.

In the embodiments of the present disclosure, the level at which the operating mode enable signal EN is represents the operating mode in which the memory is. When the memory is in the 1N mode (i.e., the first operating mode), the operating mode enable signal EN is at a high level; furthermore, the first data selector Mux1 will select to output the first control signal EVEN_CHK2 after the second delay (i.e., the signal received by the “1” input terminal). When the memory is in the 2N mode (i.e., the second operating mode), the operating mode enable signal EN is at a low level; furthermore, the first data selector Mux1 will select to output the first control signal EVEN_CHK (i.e., the signal received by the “0” input terminal).

In some embodiments of the present disclosure, referring to FIG. 10, the first control signal generation circuit 10 further includes: a first level-triggered flip-flop T1. The data input terminal D of the first level-triggered flip-flop T1 is connected to the output terminal of the first data selector Mux1, the clock input terminal of the first level-triggered flip-flop T1 receives the first frequency-divided clock signal CLK_ET, and the output terminal of the first level-triggered flip-flop T1 serves as the output terminal of the first control signal generation circuit 10.

In the embodiments of the present disclosure, with reference to FIGS. 10 and 12, a PRE signal and a PDE signal are included in the initial command address signal CA. The PDE signal is a signal that needs to be sampled and decoded currently, and the PRE signal occurs two system sampling periods earlier than the PDE signal. The PRE signal is initially sampled into a pre-sampled command address CA1 (PRE) at a high level by the even clock signal CLK_ET and is further sampled into the first command address sampling signal EVEN_CA1_OB at a low level.

In addition, the initial chip select signal CS_n is at an active level (low level) two system sampling periods before, that is, the PRE signal corresponding to the initial chip select signal CS_n is at a low level. As such, two system sampling periods before, the initial chip select signal CS_n is sampled into the first chip select sampling signal EVEN_CS_OT at a high level by the even clock signal CLK_ET.

Further, the first command address sampling signal EVEN_CA1_OB is at a low level, the first chip select sampling signal EVEN_CS_OT is at a high level, and the first control signal EVEN_CHK at a high level is obtained after the NAND operation of the first NAND gate Nand1. As such, the PRE signal representing the previous two system sampling periods is a command in the 1T CMD mode, and thus, the PDE signal in the current system sampling period is a new command that can be normally decoded.

In the embodiments of the present disclosure, with reference to FIGS. 10 and 12, if both the initial chip select signal CS_n and the pre-sampled command address CA1 (PRE) in the previous two system sampling periods are at a low level, a command in the 2T CMD mode is recognized as being executed in the previous two system sampling periods. In this case, the on-die termination command NT_ODT_CMD (not shown in the figure) is included, such that normal decoding can be performed in the current system sampling period, thereby eliminating the situation where the command after the on-die termination command NT_ODT_CMD is canceled.

In some embodiments of the present disclosure, referring to FIG. 10, the second control signal generation circuit 20 includes: a second NAND gate Nand2, a first D flip-flop DFF1, and a second data selector Mux2. Input terminals of the second NAND gate Nand2 respectively receive the second chip select sampling signal ODD_CS_OT and the second command address sampling signal ODD_CA1_OB, and the output terminal of the second NAND gate Nand2 is connected to a first input terminal (i.e., a “1” input terminal) of the second data selector Mux2. The data input terminal D of the first D flip-flop DFF1 receives the first control signal EVEN_CHK1 after the first delay, the clock input terminal of the first D flip-flop DFF1 receives the second frequency-divided clock signal CLK_OT, and the non-inverted output terminal Q of the first D flip-flop DFF1 is connected to a second input terminal (i.e., a “0” input terminal) of the second data selector Mux2. The control terminal of the second data selector Mux2 receives the operating mode enable signal EN.

In the embodiments of the present disclosure, the level at which the operating mode enable signal EN is represents the operating mode in which the memory is. When the memory is in the 1N mode (i.e., the first operating mode), the operating mode enable signal EN is at a high level; furthermore, the second data selector Mux2 will select to output the signal received by the “1” input terminal thereof. When the memory is in the 2N mode (i.e., the second operating mode), the operating mode enable signal EN is at a low level; furthermore, the first data selector Mux1 will select to output the signal received by the “0” input terminal thereof.

In some embodiments of the present disclosure, referring to FIG. 10, the second control signal generation circuit 20 further includes: a second level-triggered flip-flop T2. The data input terminal D of the second level-triggered flip-flop T2 is connected to the output terminal of the second data selector Mux2, the clock input terminal of the second level-triggered flip-flop T2 receives the first frequency-divided clock signal CLK_ET, and the output terminal Q of the second level-triggered flip-flop T2 serves as the output terminal of the second control signal generation circuit 20.

In the embodiments of the present disclosure, with reference to FIGS. 10 and 11, a PRE signal and a PDE signal are included in the initial command address signal CA. The PDE signal is a signal that needs to be sampled and decoded currently, and the PRE signal occurs one system sampling period earlier than the PDE signal. The PRE signal is initially sampled into a pre-sampled command address CA1 (PRE) at a high level and is further sampled into the second command address sampling signal ODD_CA1_OB at a low level by the odd clock signal CLK_OT.

In addition, the initial chip select signal CS_n is at an active level (low level) one system sampling period before, that is, the PRE signal corresponding to the initial chip select signal CS_n is at a low level. As such, one system sampling period before, the initial chip select signal CS_n is sampled into the second chip select sampling signal ODD_CS_OT at a high level by the odd clock signal CLK_OT.

Further, the second command address sampling signal ODD_CA1_OB is at a low level, the second chip select sampling signal ODD_CS_OT is at a high level, and the second control signal at a high level (that is, point A is at a high level) is obtained after the NAND operation of the second NAND gate Nand2. As such, the PRE signal representing the previous system sampling period is a command in the 1T CMD mode, and thus, the PDE signal in the current system sampling period is a new command that can be normally decoded.

In the embodiments of the present disclosure, with reference to FIGS. 10 and 11, if the initial chip select signal CS_n in the previous system sampling period is at a high level, or in the previous system sampling period, the initial chip select signal CS_n is at a low level and the initial command address signal CA is at a high level, no instruction operation is recognized as being performed in or a command in the 1T CMD mode is recognized as being executed in the previous system sampling period. As such, decoding may be performed in the current system sampling period using normal instructions, thereby preventing two consecutive commands in the 1T CMD mode from being mistaken for the second period of the on-die termination command NT_ODT_CMD.

In some embodiments of the present disclosure, referring to FIG. 10, the chip select signal sampling circuit 30 includes: a second D flip-flop DFF2, a third inverter Inv3, and a fourth inverter Inv4. The data input terminal D of the second D flip-flop DFF2 receives the initial chip select signal CS_n, and the clock input terminal of the second D flip-flop DFF2 receives the first frequency-divided clock signal CLK_ET. The non-inverted output terminal Q of the second D flip-flop DFF2 is connected to the input terminal of the third inverter Inv3. The output terminal of the third inverter Inv3 is connected to the input terminal of the fourth inverter Inv4. The fourth inverter Inv4 outputs the current chip select sampling signal CS.

In the embodiments of the present disclosure, referring to FIG. 10, the initial chip select signal CS_n is sampled by the second D flip-flop DFF2 triggered by the first frequency-divided clock signal CLK_ET (i.e., the even clock signal) to obtain the current chip select sampling signal CS after passing through two stages of inverters (Inv3 and Inv4).

In some embodiments of the present disclosure, referring to FIG. 10, the logic control circuit 40 includes: an OR gate Or1 and a third NAND gate Nand3. A first input terminal of the OR gate Or1 is connected to the output terminal of the first control signal generation circuit 10, and a second input terminal of the OR gate Or1 is connected to the output terminal of the second control signal generation circuit 20. The output terminal of the OR gate Or1 is connected to a first input terminal of the third NAND gate Nand3, a second input terminal of the third NAND gate Nand3 receives the current chip select sampling signal CS, and the output terminal of the third NAND gate Nand3 serves as the output terminal of the logic control circuit 40.

In the embodiments of the present disclosure, referring to FIG. 10, the OR gate Or1 receives the first control signal CS_EVEN_PP_T and the second control signal CS_EVEN_P_T respectively at two input terminals, and performs a comprehensive logical determination, where the determination result is represented by the level at which point B is. Since the first control signal CS_EVEN_PP_T is obtained in the previous two system sampling periods, and the second control signal CS_EVEN_P_T is obtained in the previous system sampling period, the determination result output by the OR gate Or1 is a logical check that combines the signals in the previous system sampling period and the previous two system sampling periods.

Further, the third NAND gate Nand3 outputs or blocks the current chip select sampling signal CS (i.e., the level at which point C is) according to the determination result output by the OR gate Or1 (i.e., the level at which point B is). With reference to FIG. 11 or 12, when point B is at a high level, the output of point D is determined by the level at which point C is, that is, when point B is at a high level, the low level at which point Cis (i.e., the current chip select sampling signal CS sampled to be at an active level) is output as the high level at which point Dis. As such, the current chip select sampling signal CS at an active level is output, and decoding can be normally performed in the current system sampling period.

It can be understood that as various command address signals converge on the command address bus, different decoding errors may be caused. In the embodiments of the present disclosure, the first control signal generation circuit obtains the first control signal according to the levels at which the chip select signal and the command address signal are in the previous two system sampling periods. The second control signal generation circuit obtains the second control signal according to the levels at which the chip select signal and the command address signal are in the previous system sampling period. Furthermore, the logic control circuit controls the output of the current chip select sampling signal (i.e., controls whether the chip select signal acts on the current command address signal) according to the first control signal and the second control signal. As such, the signals in the previous system sampling period and the previous two system sampling periods are used for a logic check, such that the command address signal in the current system sampling period can be ensured to be normally decoded, thereby avoiding decoding errors.

In some embodiments of the present disclosure, referring to FIG. 13, the command address signal sampling circuit 50 includes: a third D flip-flop DFF3 and a fourth D flip-flop DFF4. The data input terminal D of the third D flip-flop DFF3 receives the initial command address signal CA, the clock input terminal of the third D flip-flop DFF3 receives the first frequency-divided clock signal CLK_ET, and the third D flip-flop DFF3 outputs the first command address sampling signal EVEN_CA1_OB. The data input terminal D of the fourth D flip-flop DFF4 receives the initial command address signal CA, the clock input terminal of the fourth D flip-flop DFF4 receives the second frequency-divided clock signal CLK_OT, and the fourth D flip-flop DFF4 outputs the second command address sampling signal ODD_CA1_OB.

In the embodiments of the present disclosure, with reference to FIGS. 12 and 13, the third D flip-flop DFF3, triggered by the first frequency-divided clock signal CLK_ET (i.e., the even clock signal), samples the PRE signal of the initial command address signal CA in the previous two system sampling periods and outputs the first command address sampling signal EVEN_CA1_OB. The first command address sampling signal EVEN_CA1_OB is output from the inverted output terminal (i.e., the non-Q terminal) of the third D flip-flop DFF3, and thus, the first command address sampling signal EVEN_CA1_OB shown in FIG. 12 is sampled to be at a low level.

Accordingly, with reference to FIGS. 11 and 13, the fourth D flip-flop DFF4, triggered by the second frequency-divided clock signal CLK_OT (i.e., the odd clock signal), samples the PRE signal of the initial command address signal CA in the previous system sampling period and outputs the second command address sampling signal ODD_CA1_OB. The second command address sampling signal ODD_CA1_OB is output from the inverted output terminal (i.e., the non-Q terminal) of the fourth D flip-flop DFF4, and thus, the second command address sampling signal ODD_CA1_OB shown in FIG. 11 is sampled to be at a low level.

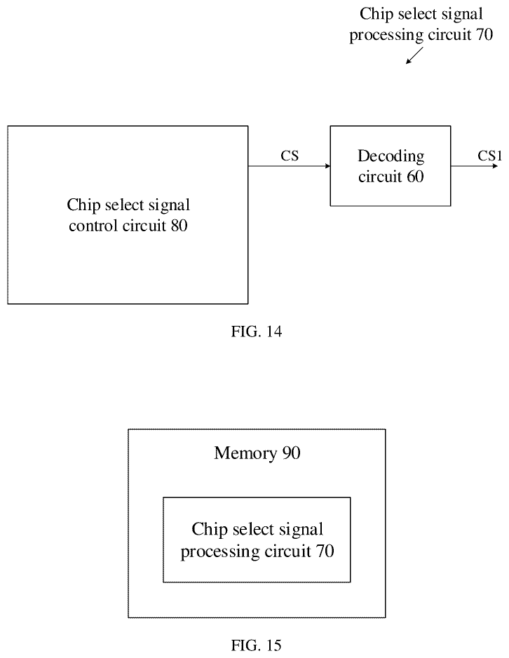

The embodiments of the present disclosure further provide a chip select signal processing circuit. As shown in FIG. 14, the chip select signal processing circuit 70 includes: the chip select signal control circuit 80 and a decoding circuit 60. The chip select signal control circuit 80 includes the technical features described in the aforementioned embodiments.

Referring to FIG. 14, the decoding circuit 60 is connected to the chip select signal control circuit 80. The decoding circuit 60 is configured to receive the current chip select sampling signal CS, decode the current chip select sampling signal CS, and then output the current chip select sampling signal (i.e., output the decoded chip select sampling signal CS1).

The embodiments of the present disclosure further provide a memory. As shown in FIG. 15, the memory 90 includes: the chip select signal processing circuit 70. The chip select signal processing circuit 70 includes the technical features described in the aforementioned embodiments.

In some embodiments of the present disclosure, referring to FIG. 15, the memory 90 is a 5th double data rate synchronous dynamic random access memory (5th double data rate synchronous dynamic random access memory, DDR5 DRAM).

It should be noted that the terms “includes”, “including”, “comprises”, “comprising”, or any other variants are intended to cover non-exclusive inclusion herein. Thus, a process, method, item, or apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments. The methods disclosed in the method embodiments provided in the present disclosure may be combined in any manner without conflict to obtain new method embodiments. The features disclosed in the product embodiments provided in the present disclosure may be combined in any manner without conflict to obtain new product embodiments. The features disclosed in the method or device embodiments provided in the present disclosure may be combined in any manner without conflict to obtain new method or device embodiments.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure.

What is claimed is:

1. A chip select signal control circuit, comprising:
a first control signal generation circuit, configured to receive a first chip select sampling signal and a first command address sampling signal, and output a first control signal at a first level when levels of the first chip select sampling signal and the first command address sampling signal meet a first preset rule, otherwise, output a first control signal at a second level, wherein the first chip select sampling signal is obtained by sampling an initial chip select signal in previous two system sampling periods, and the first command address sampling signal is obtained by sampling an initial command address signal in the previous two system sampling periods;
a second control signal generation circuit, configured to receive a second chip select sampling signal and a second command address sampling signal, and output a second control signal at the first level when levels of the second chip select sampling signal and the second command address sampling signal meet a second preset rule, otherwise, output a second control signal at the second level, wherein the second chip select sampling signal is obtained by sampling the initial chip select signal in a previous system sampling period, and the second command address sampling signal is obtained by sampling the initial command address signal in the previous system sampling period;
a chip select signal sampling circuit, configured to receive the initial chip select signal and a first frequency-divided clock signal, sample the initial chip select signal according to the first frequency-divided clock signal, and output a current chip select sampling signal; and
a logic control circuit, connected to the first control signal generation circuit, the second control signal generation circuit, and the chip select signal sampling circuit, and configured to receive the first control signal, the second control signal, and the current chip select sampling signal and output the current chip select sampling signal when the first control signal and the second control signal meet a third preset rule.

2. The chip select signal control circuit according to claim 1, wherein
the second control signal generation circuit is further configured to receive the first control signal after a first delay and a second frequency-divided clock signal, sample the first control signal after the first delay according to the second frequency-divided clock signal, and output the second control signal.

3. The chip select signal control circuit according to claim 2, wherein
the first control signal generation circuit is further configured to, in a first operating mode, apply a second delay to the first control signal and then output the first control signal; or, in a second operating mode, output the first control signal.

4. The chip select signal control circuit according to claim 3, wherein the first control signal generation circuit comprises: a first NAND gate, a first inverter, and a second inverter, wherein
input terminals of the first NAND gate respectively receive the first chip select sampling signal and the first command address sampling signal; an output terminal of the first NAND gate is connected to an input terminal of the first inverter; an output terminal of the first inverter is connected to an input terminal of the second inverter; and
the first NAND gate outputs the first control signal; the first inverter outputs the first control signal after the first delay; the second inverter outputs the first control signal after the second delay.

5. The chip select signal control circuit according to claim 3, wherein the first control signal generation circuit further comprises: a first data selector, wherein
a first input terminal of the first data selector receives the first control signal after the second delay; a second input terminal of the first data selector receives the first control signal; a control terminal of the first data selector receives an operating mode enable signal.

6. The chip select signal control circuit according to claim 5, wherein the first control signal generation circuit further comprises: a first level-triggered flip-flop, wherein
a data input terminal of the first level-triggered flip-flop is connected to an output terminal of the first data selector; a clock input terminal of the first level-triggered flip-flop receives the first frequency-divided clock signal; an output terminal of the first level-triggered flip-flop serves as an output terminal of the first control signal generation circuit.

7. The chip select signal control circuit according to claim 2, wherein the second control signal generation circuit comprises: a second NAND gate, a first D flip-flop, and a second data selector, wherein
input terminals of the second NAND gate respectively receive the second chip select sampling signal and the second command address sampling signal; an output terminal of the second NAND gate is connected to a first input terminal of the second data selector;
a data input terminal of the first D flip-flop receives the first control signal after the first delay; a clock input terminal of the first D flip-flop receives the second frequency-divided clock signal; a non-inverted output terminal of the first D flip-flop is connected to a second input terminal of the second data selector; and
a control terminal of the second data selector receives the operating mode enable signal.

8. The chip select signal control circuit according to claim 7, wherein the second control signal generation circuit further comprises: a second level-triggered flip-flop, wherein
a data input terminal of the second level-triggered flip-flop is connected to an output terminal of the second data selector; a clock input terminal of the second level-triggered flip-flop receives the first frequency-divided clock signal; an output terminal of the second level-triggered flip-flop serves as an output terminal of the second control signal generation circuit.

9. The chip select signal control circuit according to claim 1, wherein the chip select signal sampling circuit comprises: a second D flip-flop, a third inverter, and a fourth inverter, wherein
a data input terminal of the second D flip-flop receives the initial chip select signal, and a clock input terminal of the second D flip-flop receives the first frequency-divided clock signal;
a non-inverted output terminal of the second D flip-flop is connected to an input terminal of the third inverter, and an output terminal of the third inverter is connected to an input terminal of the fourth inverter; and
the fourth inverter outputs the current chip select sampling signal.

10. The chip select signal control circuit according to claim 1, wherein the logic control circuit comprises: an OR gate and a third NAND gate, wherein
a first input terminal of the OR gate is connected to the output terminal of the first control signal generation circuit; a second input terminal of the OR gate is connected to the output terminal of the second control signal generation circuit; and
an output terminal of the OR gate is connected to a first input terminal of the third NAND gate; a second input terminal of the third NAND gate receives the current chip select sampling signal; an output terminal of the third NAND gate serves as an output terminal of the logic control circuit.

11. The chip select signal control circuit according to claim 1, further comprising:
a command address signal sampling circuit, configured to receive the initial command address signal, the first frequency-divided clock signal, and the second frequency-divided clock signal, sample the initial command address signal into the first command address sampling signal according to the first frequency-divided clock signal, and sample the initial command address signal into the second command address sampling signal according to the second frequency-divided clock signal.

12. The chip select signal control circuit according to claim 11, wherein the command address signal sampling circuit comprises: a third D flip-flop and a fourth D flip-flop, wherein
a data input terminal of the third D flip-flop receives the initial command address signal, a clock input terminal of the third D flip-flop receives the first frequency-divided clock signal, and the third D flip-flop outputs the first command address sampling signal; and
a data input terminal of the fourth D flip-flop receives the initial command address signal, a clock input terminal of the fourth D flip-flop receives the second frequency-divided clock signal, and the fourth D flip-flop outputs the second command address sampling signal.

13. A chip select signal processing circuit, comprising: the chip select signal control circuit according to claim 1 and a decoding circuit, wherein
the decoding circuit is connected to the chip select signal control circuit, and is configured to receive a current chip select sampling signal, decode the current chip select sampling signal, and then output the current chip select sampling signal.

14. A memory, comprising the chip select signal processing circuit according to claim 13.

15. The memory according to claim 14, wherein the memory is a 5th double data rate synchronous dynamic random access memory (DDR5 DRAM).
